(19) United States
(12) Patent Application Publication
(10) Pub. No.: US 2011/0126085 A1
(43) Pub. Date: May 26, 2011

(54) METHOD OF SIGNATURE VERIFICATION

(75) Inventors: Yannick Teglia, Belcodene (FR); William Orlando, Peynier (FR)

(73) Assignee: STMicroelectronics (Rousset) SAS, Rousset (FR)

(21) Appl. No.: 12/943,471

(22) Filed: Nov. 10, 2010

(30) Foreign Application Priority Data
Nov. 18, 2009 (FR) 09/58142

(51) Int. Cl. H03M 13/09; G06F 11/07

(52) U.S. Cl. 714/819; 714/E11.024

(57) ABSTRACT

A method of detecting a fault including generating at least one blinded data value based on at least one input value and at least one blinding parameter selected from a plurality of blinding parameters generating a first signature based on said at least one blinded data value; selecting, from a memory storing a plurality of reference signatures, one or more reference signatures and comparing said first signature with said one or more reference signatures in order to detect a fault.

### CROSS REFERENCE TO RELATED APPLICATIONS

This application claims the priority benefit of French patent application Ser. No. 09/58142, filed on Nov. 19, 2009, entitled “Method of Signature Verification,” which is hereby incorporated by reference to the maximum extent allowable by law.

### BACKGROUND OF THE INVENTION

1. Field of the Invention

The present invention relates to a method and circuitry for signature verification, and in particular to a method and a circuitry for verifying a signature to detect one or more faults.

2. Discussion of the Related Art

Integrated circuits may comprise circuitry that is considered sensitive in view of the security of the data it manipulates, such as authentication keys, signatures, etc., or in view of the algorithms it uses, such as encryption or decryption algorithms. Such information is desired to be kept secret, meaning that it should not be communicated to or otherwise be detectable by third parties or unauthorized circuits.

A common process for pirating information manipulated by an integrated circuit consists in detecting the zones of the circuit that are used during the processing of that information. For this, the circuit is activated or placed in a functional environment and data packets to be encoded are introduced at an input. While the data is being processed, the surface of the integrated circuit is swept by a laser to inject faults in the functioning of the circuit. By analysing in parallel the outputs of the circuit, this enables the zones of the circuit that process the data to be determined. Having localized these zones, the pirate can concentrate attacks on these zones in order to determine the secret data being processed.

Signatures provide a way of protecting a circuit against fault attacks. A signature is generated based on one or more data values that will be used by an algorithm. A signature is then generated on the same data values after they have been used by the algorithm. A difference in the two signatures will indicate the occurrence of an attack. Once the detection circuit has detected such an attack, it can trigger a counter measure, such as resetting the circuit, and/or incrementing a counter, which renders the integrated circuit permanently inactive once a certain number of faults have been detected.

In order to be effective at detecting fault attacks, a signature relating to a given block of data is preferably computed in advance, and then recomputed based on the block of data after this data has been used for example in one or more algorithms. However, the data as used during the algorithm is often altered, for example by blinding or other operations performed on the data. This leads to a problem, such alterations in the data can lead to a mismatch between the signatures even when no fault attack has occurred.

It would be desirable to provide circuits in which fault attacks can be detected, even after the original data has been transformed by one or more algorithms.

### SUMMARY OF THE INVENTION

It is an aim of embodiments of the present invention to at least partially address one or more problems in the prior art.

According to one aspect of the present invention, there is provided a method of detecting a fault comprising: generating at least one blinded data value based on at least one input value and at least one blinding parameter selected from a plurality of blinding parameters; generating a first signature based on said at least one blinded data value; selecting, from a memory storing a plurality of reference signatures, one or more reference signatures; and comparing said first signature with said one or more reference signatures in order to detect a fault.

According to one embodiment, the method further comprises, prior to the step of selecting one or more reference signatures from said memory, generating said plurality of reference signatures based on said plurality of blinding parameters, and storing said values in said memory.

According to another embodiment, the step of selecting one or more reference signatures from said memory comprises selecting a reference signature based on the selected at least one parameter.

According to another embodiment, the step of selecting one or more reference signatures from said memory comprises selecting each of said plurality of reference signatures in turn, wherein said comparing step is performed between the first signature and each of said plurality of reference signatures, a fault being detected if none of said reference signatures matches said first signature.

According to another embodiment, the first signature and said plurality of reference signatures are values indicating a difference with respect to an base signature value generated based on said at least one input data value.

According to another embodiment, the blinding parameters are encryption keys and the at least one blinded data values are encrypted or decrypted data values generated based on said selected parameter value.

According to another embodiment, there are a plurality of the blinded data values, and the first signature is generated by applying one of the following functions between each of said blinded data values: a hash function; an XOR function; a multiplication; and an addition.

According to another embodiment of the present invention, there is provided a method of detecting a fault attack comprising the above method of detecting a fault, wherein a fault attack is detected if a difference is detected between the first signature and each of the one or more reference signatures.

According to another embodiment of the present invention, there is provided a method of verifying authenticity of encrypted or decrypted data comprising the above method of detecting a fault, wherein the plurality of parameters are encryption keys, and wherein the encrypted data is determined not to be authentic if a difference is detected between the first signature and each of the one or more reference signatures.

According to another embodiment of the present invention, there is provided circuitry for detecting a fault comprising: a function unit arranged to generate at least one blinded data value based on at least one input value and at least one blinding parameter selected from a plurality of blinding parameters; a signature block arranged to generate a first signature based on said at least one blinded data value; a memory storing a plurality of reference signatures; means for selecting one or more of said reference signatures; and a comparator arranged to compare said first signature with said one or more reference signatures in order to detect a fault.

According to further embodiments of the present invention, there is provided an integrated circuit comprising the above circuitry, and an electronic device, integrated circuit (IC) card and integrated circuit (IC) card reader comprising the integrated circuit.

### BRIEF DESCRIPTION OF THE DRAWINGS

The foregoing and other purposes, features, aspects and advantages of the invention will become apparent from the following detailed description of embodiments, given by way of illustration and not limitation with reference to the accompanying drawings, in which:

FIG. 1 illustrates circuitry for detecting a fault attack according to one embodiment;

FIGS. 2 to 4 illustrate circuits for detecting a fault according to embodiments of the present invention; and

FIG. 5 illustrates an electronic device according to embodiments of the present invention.

### DETAILED DESCRIPTION

For clarity, only those steps and elements useful in an understanding of the invention have been represented in the figures and will be described in detail. In particular, the circuitry for resetting an integrated circuit or rendering it inactive upon detection of one or more faults has not been detailed, the invention being applicable to any such circuits. Furthermore, the primary functions of the integrated circuit being protected have not been described in detail, the invention being compatible with integrated circuits implementing any sensitive functions, such as encryption or decryption, or other functions involving sensitive data.

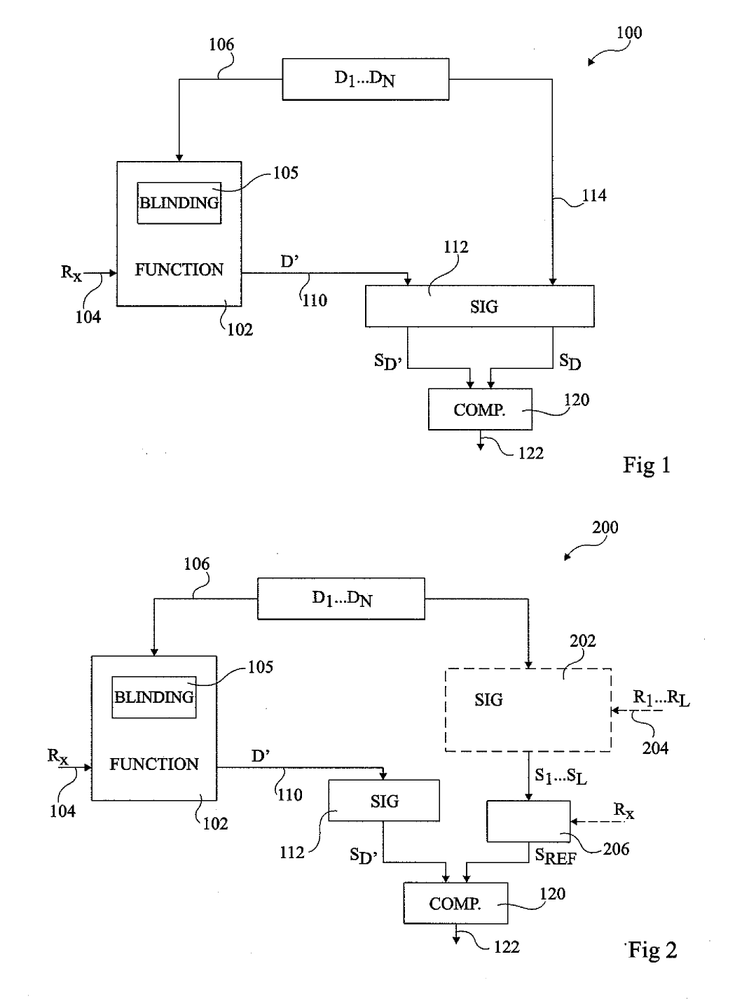

FIG. 1 illustrates a circuit 100 comprising a function unit 102, which, for example, implements an algorithm involving sensitive data, such as an encryption key or the like. The unit 102 comprises an input line 104 for receiving a blinding parameter Rₓ used to implement the algorithm. The blinding parameter Rₓ is for example a pseudo random value, an encryption key or other data value, that could be a secret value, or publicly available. For example, the function unit 102 comprises a blinding block 105, which applies a blinding algorithm to the data values D₁ to D_{N} to provide some protection against side channel attacks. In this case, the blinding parameter Rₓ is for example a pseudo-random blinding value, based on which the blinding function is applied.

The function unit 102 also receives data values D₁ to D_{N} on an input line 106. Based on these data values and the parameter Rₓ, the function unit 102 generates one or more output values D′ on an output line 110 as a function of D₁ to D_{N} and Rₓ, in other words D′=f(D₁ . . . D_{N},Rₓ). The output line 110 is coupled to a signature block 112. The signature block 112 also receives the original data values D₁ to D_{N} on a line 114, and generates a signature S_{D} based on the data values D₁ to D_{N}, and a signature S_{D′} based on the one or more data values D′. These two signatures S_{D} and S_{D′} are compared by comparator 120 to provide an output 122 indicating whether a fault attack is detected.

A difficulty is that after a function has been applied by the function unit 102 to the data values D₁ to D_{N} based on the blinding parameter Rₓ, it is likely that the data values will have been changed to such an extent that the signature S_{D′} is no longer equal to the signature S_{D} when no fault attack has occurred. Furthermore, even if it is possible to carefully choose the function ƒ(D₁ . . . D_{N},Rₓ) and the signature function such that for any value of Rₓ the signatures match when there is no fault, this greatly limits the choice of these functions. In the case of the function ƒ(D₁ . . . D_{N},Rₓ), this function serves a main purpose of blinding the data values D₁ to D_{N}. Limiting the choice for this function may thus reduce the effectiveness of this main purpose. In the case of the signature, some signature functions can be more effective in detecting a fault injected at any bit position in any of the input values, and thus limiting the choice of signature functions can limit the extent that faults can be detected.

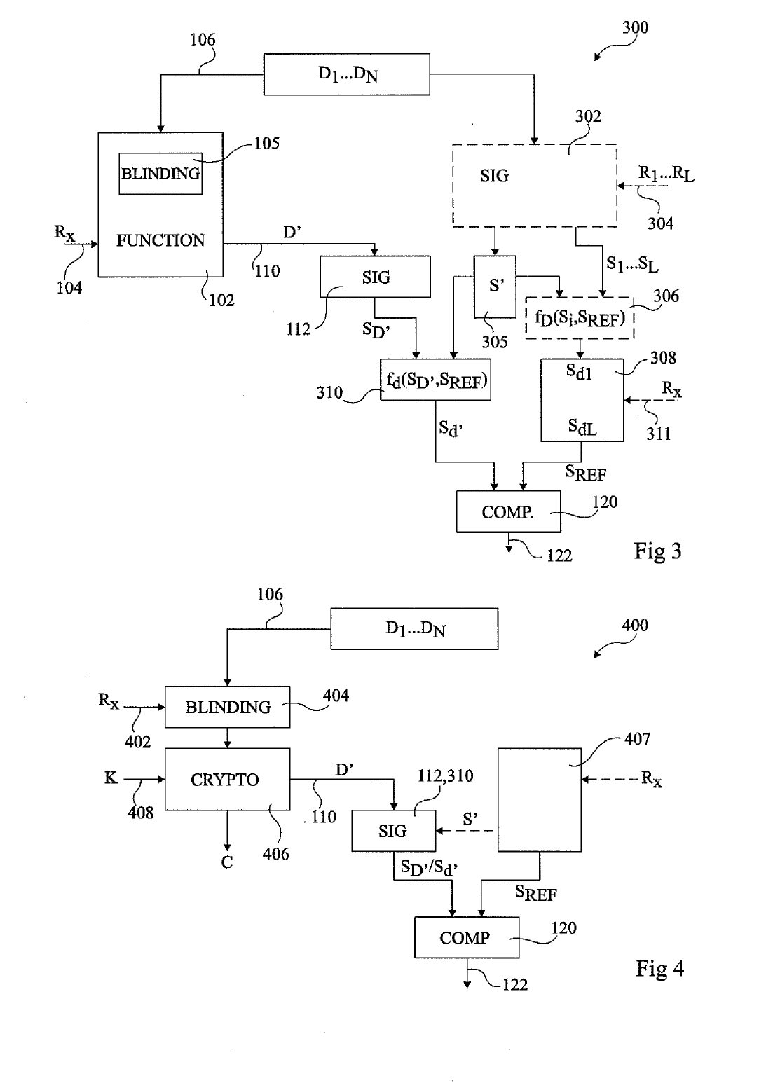

FIG. 2 illustrates circuitry 200 for detecting a fault, which comprises many of the same elements as those of FIG. 1, which are labelled with like reference numerals and will not be described again in detail.

In the circuitry 200, the signature block 112 generates the signature S_{D′} based on the values D′ provided by function unit 102 on line 110. A further signature block 202 generates, for example during an initialization phase, a number of signatures S₁ to S_{L}, each of which is based on the data values D₁ to D_{N}, after a corresponding one of the parameters R₁ to R_{L} has been applied. In particular, the signature block 202 receives on an input line 204 the parameter values R₁ to R_{L}. This is the group of parameter values from which the parameter Rₓ provided to function unit 102 is selected. The signatures S₁ to S_{L} are each generated by applying to the values D₁ to D_{N} the one or more operations, as performed by the function unit 102, based on the corresponding parameter R₁ to R_{L}. In particular, the signature block 202 performs the same function ƒ(D₁ . . . D_{N},Rₓ) as performed by the function unit 102, but with the parameter Rₓ replaced by each of the parameters R₁ to R_{L} in turn. For example, assuming that the function unit 102 blinds the data values D₁ to D_{N} by performing the XOR of each value with the parameter Rₓ, the signature block 202 also blinds the data values D₁ to D_{N} based on each of the parameters R₁ to R_{L} in turn, and generates the corresponding signatures S₁ to S_{L} based on each group of blinded values.

The signature block 202, for example, stores the signatures S₁ to S_{L} in a memory 206, which is, for example, a ROM (read only memory) or RAM (random access memory). One or more of the signatures S₁ to S_{L} are provided as a reference signature value S_{REF} from the memory 206 to the comparator 120 for comparison with the signature S_{D′} generated by signature block 112.

In some embodiments, each of the signatures S₁ to S_{L} is provided in turn by the memory 206 as the reference signature S_{REF} and is compared by comparator 120 with the signature S_{D′}. In this case, it is determined that a fault attack has been detected if none of these signatures S₁ to S_{L} matches the signature S_{D′}. Such a systematic comparison of each of the signatures S₁ to S_{L} is for example performed if it is unlikely that a fault introduced into one of the data values D₁ to D_{N} would cause a modified signature S_{D′} which is also among one of the signatures S₁ to S_{L}. For example, this would be true if the values R₀ to R_{L} are just a few values taken from a possible set R for a given number of bits of the blinding value. This can be expressed by the following formula:

Cardinal{R₁ . . . R_{L}}<<2sizeof(Rᵢ)

where Cardinal{R₁, . . . , R₁} is the number of values in the set R₁ to R_{L}, equal to L, sizeof(Rᵢ) is the number of bits of each value Rᵢ of the set R, and “<<” means much greater than, for example more than two times greater. For example, R is a 6-bit binary value, meaning that the number of possible values is 2⁶, equal to 64, whereas the values R₁ to R_{L} could be just the values 1, 12, 23, 36, 44 and 59 respectively. This leads to a relatively low probability that an error of one of the input values blinded with the value Rₓ selected from R₀ to R_{L} would lead to another valid signature.

Alternatively, the value of the parameter Rₓ is provided to the memory 206, such that just one corresponding signature Sₓ of the signatures S₁ to S_{L} is selected from memory 206 for comparison with signature S_{D′}. Thus signature S_{REF} is selected based on the particular value Rₓ applied by the function unit when generating the output values D′. An advantage of this solution is that only one comparison is performed, leading to a faster result.

In some embodiments, the data values D₁ to D_{N} are known in advance, and the signature block 202 forms part of an initialisation device that generates the signatures S₁ to S_{L} during an initialisation phase, and stores these values in the memory 206, which is for example a ROM or RAM. The signatures S₁ to S_{L} are then not recalculated during the lifetime of the device, or if an update is needed, new values could be loaded into the memory 206. The signature block 202 is then not present in the final device containing the other elements of FIG. 2, and is represented in dashed lines in FIG. 2 for this reason.

In alternative embodiments, the data values D₁ to D_{N} could be packets of data that are variable with time, and therefore can not be known in advance. In this case the signature block 202 may generate the signatures S₁ to S_{L} “on the fly” for each new group of data values D₁ to D_{N}.

FIG. 3 illustrates fault detection circuitry 300, in which elements 102 to 112 are the same as those of FIG. 2 and will not be described again in detail. In the embodiment of FIG. 3, the signature block 202 of FIG. 2 is replaced by a signature block 302, which not only generates the signature values S₁ to S_{L} based on the blinding parameters R₁ to R_{L} received on an input line 304, but also generates a base signature value S′. The base signature value S′ is, for example, the signature generated for the data values D₁ to D_{N} without any of the parameters R₁ to R_{L} applied, or simply one of the signatures S₁ to S_{L}. The base signature value S′ is stored in a memory 305, which is for example a ROM or RAM.

The signatures S₁ to S_{L} and the base signature value S′ are provided to a difference block 306, which determines the difference between the base signature value S′ and each of the signatures S₁ to S_{L}, by applying a function ƒ_{D}(Sᵢ,S′), where Sᵢ is each of the signatures S₁ to S_{L}. The resulting signatures S_{d1} to S_{dL} indicate the difference between the base signature value S′ and the corresponding signature S₁ to S_{L}. The signatures S_{d1} to S_{dL} are, for example, smaller than the corresponding signatures S₁ to S_{L}, and are, for example, based on one of the following functions:

S_{di}=Sᵢ−S′;

S_{di}=Sᵢ/S′;

S_{di}=SᵢXORS′, performed bit by bit;

S_{di}=Hamming Weight(Sᵢ)−Hamming Weight(S′); or

S_{di}=Hamming Weight(SᵢXORS′).

where Hamming Weight(X) is the number of bits in the value X different from the zero value.

The signatures S_{d1} to S_{dL} are stored in a memory 308.

The base signature value S′ is also provided to a difference block 310, which receives the signature S_{D′} from the signature block 112, and applies the same function ƒ_{D}(Sᵢ,S′) as block 306, but for which Sᵢ is replaced by S_{D′}. This determines a difference value S_{d′} provided to the comparator 120.

Like memory 206, memory 308 provides reference signatures S_{REF} to the comparator 120, which in this embodiment are compared to the signature S_{d′} from the signature difference block 310. As with the memory 206, each signature from memory 308 could be provided in turn to the comparator 120 for comparison with the value S_{d′} or one particular value S_{dx} could be selected based on the value of Rₓ provided to the memory 308 on an input line 311.

In the embodiments of FIGS. 2 and 3, the selection of Rₓ from the group of blinding parameters R₁ to R_{L} for function unit 102 could be pseudo-random, or based on a criterion, such as the which encryption key is to be used for a given encryption operation, assuming the parameter Rₓ is a key. More generally, the blinding parameter Rₓ could be one or more values applied by the function unit 102 to the data values D₁ to D_{N}, including an encryption key or the like.

For example, the function unit 102 could perform encryption or decryption based on an algorithm such as AES or DES, and the function ƒ(D₁ . . . D_{N},Rₓ) could therefore be the encryption or decryption function, in which D₁ to D_{N} are data packets (plaintext/cipher text) to be encrypted or decrypted, and blinding parameter Rₓ is the encryption/decryption key. The resulting data values D′ are thus the encrypted or decrypted packets (cipher text/plaintext). The memory 206, 308 or 406, for example, stores reference signatures generated based on each of a plurality of different encryption/decryption keys R₁ to R_{L}. Thus, in addition to or instead of being used to detect a fault attack, a comparison of the signatures provides verification that the key Rₓ used by the function unit 102 is one of the plurality of valid encryption or decryption keys R₁ to R_{L}. An advantage of this authentication technique is that it can be performed without knowing the actual key used to perform a given encryption or decryption operation. Thus the signature block 112, the memory 206, 308 or 406 and the comparator 120 are, for example, part of an authentication device, which is separate from the function unit 102, and does not have access to the encryption/decryption keys.

Alternatively, the function ƒ(D₁ . . . D_{N},Rₓ) could result in a series of blinded values D₁′ to D_{N}′, in which each value Dⱼ, for j equal to 1 to N, is generated as D_{j′}=Dⱼ XOR Rₓ. As a further example, the function could be a circular left or right shift of Dⱼ by a number of positions Rₓ, or Dⱼ mod Rₓ. The values D₁ to D_{N} could, for example, represent the values of an SBOX table used in an AES or DES encryption or decryption algorithm, or the metadata of a SHA-1 or SHA-2 algorithm. An example of this embodiment will now be described with reference to FIG. 4.

FIG. 4 illustrates circuitry 400 in which the blinding parameter Rₓ is received on an input line 402 to a blinding unit 404, which implements the blinding function prior to a cryptographic function implemented by a crypto block 406. Block 406 also receives a key on an input line 408, and generates an output C, which is, for example, encrypted or decrypted data. In this example, the outputs on line 110 are provided from the crypto block 406, and for example correspond to the blinded values D₁′ to D_{N}′ of the original data values D₁ to D_{N}. These values are provided to the signature block 112, which may or may not include the functionality of the signature difference block 310 of FIG. 3. The result is thus either the signature S_{D′} directly, or a signature S_{d′}, indicating the difference with respect to a base signature value S′, which can be stored in a memory 407. The memory 407, for example, stores signatures S₁ to S_{L} or S_{d1} to S_{dL}, and outputs one or more of these values as S_{REF} to the comparator 120 for comparison with the signature S_{D′} or S_{d′} in order to detect a fault.

In the embodiments of FIGS. 2, 3 and 4, the signature function applied by the signature blocks 112, 202 and 302 is for example an XOR, addition or multiplication operation applied between each of the data values, a hash function, SHA-1 or SHA-2 algorithms, MD5 algorithm, CRC (cyclic redundancy code) algorithm, or any other type of signature function the result of which can allow a fault injected in one of the underlying sets of data values to be detected.

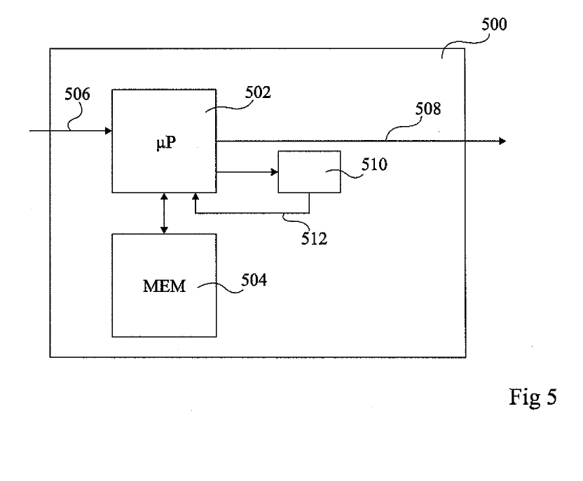

FIG. 5 illustrates an electronic device 500 comprising a microprocessor 502, a memory block 504, and an input line 506, which provides input values to the microprocessor 502. The microprocessor 502 provides output values on an output line 508. Furthermore, protection circuitry 510 comprises the signature block 112, memory 206, 308 or 407, and comparator 120 and in some embodiments the memory 305 and signature difference block 310, as described above. This circuitry 510 provides an alert signal on an output line 512 provided back to the microprocessor 502, which for example triggers a reset of the microprocessor 502 and/or increments a counter (not shown in FIG. 5), which will permanently deactivate the microprocessor once a certain count value has been reached.

The electronic device 500 is for example an IC (integrated circuit) card, such as a smart card, an IC card reader, such as a credit card payment terminal, or other device handling sensitive information.

An advantage of the embodiment described herein is that signature verification is possible even when a function is applied to the original data values based on one or more parameters. A further advantage of the embodiments described herein is that the signature function is not limited to any particular function.

An advantage of storing difference values S_{d1} to S_{dL} as the signatures is that these values may occupy less space that the full signatures, and use relatively little processing resources for their generation.

Having thus described at least one illustrative embodiment of the invention, various alterations, modifications and improvements will readily occur to those skilled in the art.

For example, it will be apparent to those skilled in the art that the embodiments described herein could be applied to a broad range of circuits in which signature verification is used to detect faults.

Furthermore, it will be apparent to those skilled in the art the embodiments described herein could be implemented in software, hardware or a combination thereof. Additionally, the features described in relation to the various embodiments could be combined in any combination in alternative embodiments.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method of detecting a fault comprising:
generating at least one blinded data value based on at least one input value and at least one blinding parameter selected from a plurality of blinding parameters;
generating a first signature based on said at least one blinded data value;
selecting, from a memory storing a plurality of reference signatures, one or more reference signatures; and
comparing said first signature with said one or more reference signatures in order to detect a fault.

2. The method of claim 1, further comprising, prior to the step of selecting one or more reference signatures from said memory, generating said plurality of reference signatures based on said plurality of blinding parameters, and storing said values in said memory.

3. The method of claim 1, wherein said step of selecting one or more reference signatures from said memory comprises selecting a reference signature based on the selected at least one parameter.

4. The method of claim 1, wherein said step of selecting one or more reference signatures from said memory comprises selecting each of said plurality of reference signatures in turn, wherein said comparing step is performed between the first signature and each of said plurality of reference signatures, a fault being detected if none of said reference signatures matches said first signature.

5. The method of claim 1, wherein said first signature and said plurality of reference signatures are values indicating a difference with respect to an base signature value generated based on said at least one input data value.

6. The method of claim 1, wherein said blinding parameters are encryption keys and said at least one blinded data values are encrypted or decrypted data values generated based on said selected parameter value.

7. The method of claim 1, wherein there are a plurality of said blinded data values, and said first signature is generated by applying one of the following functions between each of said blinded data values:
a hash function;
an XOR function;
a multiplication; and
an addition.

8. A method of detecting a fault attack comprising the method of detecting a fault of claim 1, wherein a fault attack is detected if a difference is detected between the first signature and each of the one or more reference signatures.

9. A method of verifying authenticity of encrypted or decrypted data comprising the method of detecting a fault of claim 1, wherein the plurality of parameters are encryption keys, and wherein the encrypted or decrypted data is determined not to be authentic if a difference is detected between the first signature and each of the one or more reference signatures.

10. Circuitry for detecting a fault comprising:
a function unit arranged to generate at least one blinded data value (D′) based on at least one input value and at least one blinding parameter selected from a plurality of blinding parameters;
a signature block arranged to generate a first signature based on said at least one data value;
a memory storing a plurality of reference signatures;
means for selecting one or more of said reference signatures; and
a comparator arranged to compare said first signature with said one or more reference signatures in order to detect a fault.

11. An integrated circuit comprising the circuitry of claim 10.

12. An electronic device comprising the integrated circuit of claim 11.

13. An integrated circuit (IC) card comprising the integrated circuit of claim 11.

14. An integrated circuit (IC) card reader comprising the integrated circuit of claim 11.
